(19) United States
(12) Patent Application Publication
(10) Pub. No.: US 2026/0057940 A1
(43) Pub. Date: Feb. 26, 2026

(54) SEMICONDUCTOR DEVICE AND OPERATING METHOD OF SEMICONDUCTOR DEVICE

(71) Applicant: SK hynix Inc., Icheon-si (KR)

(72) Inventor: Ung Hee PARK, Icheon-si (KR)

(21) Appl. No.: 19/187,721

(22) Filed: Apr. 23, 2025

(30) Foreign Application Priority Data
Aug. 26, 2024 (KR) 10-2024-0114539

(51) Int. Cl. G11C 16/10; G11C 16/08; G11C 16/24; G11C 16/26

(52) U.S. Cl. CPC G11C 16/102; G11C 16/08; G11C 16/24; G11C 16/26

(57) ABSTRACT

A semiconductor device may include a column switch that electrically connects a global bit line to a bit line or disconnects the global bit line from the bit line, a row switch that electrically connects a global word line to a word line or disconnects the global word line from the word line, and a memory cell electrically connected between the bit line and the word line. During a write operation, one or both of a turn-on degree of the column switch and the row switch may be changed.

### CROSS-REFERENCE TO RELATED APPLICATION

This application claims priority under 35 U.S.C. § 119(a) to Korean Patent Application No. 10-2024-0114539 filed on Aug. 26, 2024, which is incorporated herein by reference in its entirety.

### BACKGROUND

### 1. Technical Field

Embodiments of the present disclosure relate to an integrated circuit technology, and particularly, to a semiconductor device and an operating method of the semiconductor device.

### 2. Related Art

Recently, with the miniaturization, low power consumption, high performance, diversification, and the like of electronic devices, semiconductor devices capable of storing information in various electronic appliances such as computers and portable communication devices are desirable. The semiconductor devices may be roughly classified into volatile memory devices and nonvolatile memory devices. The volatile memory devices may retain data only when power is supplied, and the nonvolatile memory devices may retain data even though no power is supplied.

Among the nonvolatile memory devices, an NAND type memory is representative, and next-generation memories under development include a ferroelectric RAM (FRAM), a magnetic RAM (MRAM), a phase-change RAM (PRAM), a polymer RAM (PoRAM), a resistance RAM (ReRAM), and the like.

### SUMMARY

In an embodiment, a semiconductor device may include: a column switch that electrically connects a global bit line to a bit line or disconnects the global bit line from the bit line; a row switch that electrically connects a global word line to a word line or disconnects the global word line from the word line; and a memory cell electrically connected between the bit line and the word line. During a write operation, a turn-on degree of the column switch and a turn-on degree of the row switch is changed.

In an embodiment, an operating method of a semiconductor device may include: electrically connecting a global bit line to a bit line during a write operation; electrically connecting a global word line to a word line during the write operation; determining a direction of a current to flow through a memory cell connected between the bit line and the word line; and adjusting an amount of the current flowing in a specific direction.

In an embodiment, a semiconductor device may include: a memory cell that stores data; at first transistor that electrically connects a global bit line to a bit line or disconnects the global bit line from the bit line; and a second transistor that electrically connects a global word line to a word line or disconnects the global word line from the word line. During a write operation, a turn-on degree of the first transistor is changed according to a level of a voltage applied to a gate of the first transistor, a turn-on degree of the second transistor is changed according to a level of a voltage applied to a gate of the second transistor, or both.

### BRIEF DESCRIPTION OF THE DRAWINGS

FIG. 1 is a diagram illustrating a configuration of a semiconductor device in accordance with an embodiment of the present disclosure.

FIG. 2 is a diagram for explaining a first write operation of a semiconductor device in accordance with an embodiment of the present disclosure.

FIG. 3 is a diagram for explaining a second write operation of a semiconductor device in accordance with an embodiment of the present disclosure.

FIGS. 4, 5, and 6 are diagrams for explaining a data storage operation of a memory cell for a write operation of a semiconductor device in accordance with an embodiment of the present disclosure.

FIG. 7 is a diagram for explaining a read operation of a semiconductor device in accordance with an embodiment of the present disclosure.

### DETAILED DESCRIPTION

Various embodiments are directed to providing a semiconductor device that writes and reads a memory cell at multiple levels and an operating method of the semiconductor device.

Because a memory cell can be written and read at multiple levels, there is an effect of improving the data storage capacity of a semiconductor device without process changes.

Hereafter, some embodiments of the present disclosure will be described with reference to the accompanying drawings. As used herein, including in the claims, a list of items prefaced by a phrase such as “at least one of” or “one or more of” or “one or both of” indicates an inclusive list such that, for example, a list of “at least one of A and B” and a list of “one or both of A and B” each indicate A, or B, or AB (i.e., A and B). Moreover, the term “a” or “an” entity refers to one or more of that entity. For example, the term “a” or “an,” “one or more,” and “at least one” can be used interchangeably herein.

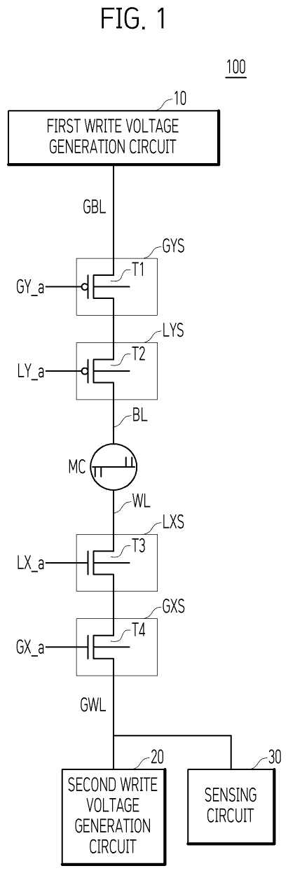

FIG. 1 is a diagram illustrating a configuration of a semiconductor device 100 in accordance with an embodiment of the present disclosure.

The semiconductor device 100 in accordance with an embodiment of the present disclosure includes a memory cell MC connected between a bit line BL and a word line WL. For convenience of description, one memory cell MC connected between one bit line BL and one word line WL is described as an example, but embodiments of the present disclosure are not limited to such a configuration. For example, the semiconductor device 100 illustrated in FIG. 1 includes one selected bit line BL among a plurality of bit lines (not illustrated), one selected word line WL among a plurality of word lines (not illustrated), and a memory cell MC connected between the selected bit line BL and the selected word line WL. Here, a plurality of memory cells (not illustrated) may be connected between the plurality of bit lines and the plurality of word lines, and the memory cell MC connected between the selected bit line BL and the selected word line WL is one memory cell MC selected from the plurality of memory cells.

Referring to FIG. 1, the semiconductor device 100 in accordance with an embodiment of the present disclosure includes a first column switch (e.g., a global column switch) GYS, a second column switch (e.g., a local column switch) LYS, a first row switch (e.g., a global row switch) GXS, a second row switch (e.g., a local row switch) LXS, and the memory cell MC. The semiconductor device 100 in accordance with an embodiment of the present disclosure may further include a first write voltage generation circuit 10, a second write voltage generation circuit 20, and a sensing circuit 30 that can drive the bit line BL and the word line WL to store data in the memory cell MC or sense the stored data. For example, the first and second write voltage generation circuit 10 and 20 can drive the bit line BL and the word line WL to store data in the memory cell MC, and the sensing circuit 30 can drive the bit line BL and the word line WL to sense the stored data.

In an embodiment, the global column switch GYS is turned on or off on the basis of a global column address signal GY_a. The turned-on global column switch GYS electrically connects a global bit line GBL to the local column switch LYS. The turn-on degree of the global column switch GYS is determined on the basis of the voltage level of the global column address signal GY_a. The turned-off global column switch GYS electrically disconnects the global bit line GBL from the local column switch LYS.

For example, the global column switch GYS includes a first transistor T1.

In an embodiment, the first transistor T1 includes a control terminal (e.g., a gate) to which the global column address signal GY_a is input, and a first terminal (e.g., a drain) and a second terminal (e.g., a source) to which the global bit line GBL and the local column switch LYS are connected, respectively. For example, the first transistor T1 is a P-type transistor. As the voltage level of the global column address signal GY_a decreases, the turn-on degree of the first transistor T1 increases. As the turn-on degree increases, the first transistor T1 allows a large amount of current to flow therethrough. In other words, as the voltage level of the global column address signal GY_a decreases, the turn-on degree of the first transistor T1 increases while the turn-on resistance of the first transistor T1 decreases, thereby increasing an amount of current flowing through the first transistor T1. On the other hand, as the voltage level of the global column address signal GY_a increases, the turn-on degree of the first transistor T1 decreases. As the turn-on degree decreases, the first transistor T1 allows a small amount of current to flow therethrough.

In an embodiment, the local column switch LYS is turned on or off on the basis of a local column address signal LY_a. The turned-on local column switch LYS electrically connects the global column switch GYS to the bit line BL. The turn-on degree of the local column switch LYS is determined by the voltage level of the local column address signal LY_a. The turned-off local column switch LYS electrically disconnects the global column switch GYS from the bit line BL.

For example, the local column switch LYS includes a second transistor T2.

In an embodiment, the second transistor T2 includes a control terminal (e.g., a gate) to which the local column address signal LY_a is input, and a first terminal (e.g., a drain) and a second terminal (e.g., a source) to which the global column switch GYS and the bit line BL are connected, respectively. For example, the second transistor T2 is a P-type transistor. As the voltage level of the local column address signal LY_a decreases, the turn-on degree of the second transistor T2 increases. In addition, as the turn-on degree increases, the second transistor T2 allows a large amount of current to flow therethrough. On the other hand, as the voltage level of the local column address signal LY_a increases, the turn-on degree of the second transistor T2 decreases. In addition, as the turn-on degree decreases, the second transistor T2 allows a small amount of current to flow therethrough.

In an embodiment, the memory cell MC is connected between the bit line BL and the word line WL. The memory cell MC is connected to the local column switch LYS through the bit line BL. The memory cell MC is connected to the local row switch LXS through the word line WL. The memory cell MC is a memory cell having a bidirectional current characteristic. For example, the threshold voltage level of the memory cell MC is determined on the basis of the direction of a current passing through the memory cell MC during a write operation. When a current in a first direction passes through the memory cell MC, the memory cell MC has a different threshold voltage level compared to a case in which a current in a second direction passes through the memory cell MC. The first direction and the second direction are directions different from each other. For example, the memory cell MC is a variable resistance memory cell.

In an embodiment, the memory cell MC includes a chalcogenide material. The memory cell MC is a memory cell that stores data through a phase change of the chalcogenide material according to a change in the direction and amount of an applied current.

In an embodiment, the local row switch LXS is turned on or off on the basis of a local row address signal LX_a. The turned-on local row switch LXS electrically connects the word line WL to the global row switch GXS. The turn-on degree of the local row switch LXS is determined by the voltage level of the local row address signal LX_a. On the other hand, the turned-off local row switch LXS electrically disconnects the word line WL from the global row switch GXS.

For example, the local row switch LXS includes a third transistor T3.

In an embodiment, the third transistor T3 has a control terminal (e.g., a gate) to which the local row address signal LX_a is input, and a first terminal (e.g., a drain) and a second terminal (e.g., a source) to which the word line WL and the global row switch GXS are connected, respectively. For example, the third transistor T3 is an N-type transistor. As the voltage level of the local row address signal LX_a increases, the turn-on degree of the third transistor T3 increases. In addition, as the turn-on degree increases, the third transistor T3 allows a large amount of current to pass therethrough. On the other hand, as the voltage level of the local row address signal LX_a decreases, the turn-on degree of the third transistor T3 decreases. In addition, as the turn-on degree decreases, the third transistor T3 allows a small amount of current to pass therethrough.

In an embodiment, the global row switch GXS is turned on or off on the basis of a global row address signal GX_a. The turned-on global row switch GXS electrically connects the local row switch LXS and a global word line GWL. The turn-on degree of the global row switch GXS is determined on the basis of the voltage level of the global row address signal GX_a. On the other hand, the turned-off global row switch GXS electrically disconnects the local row switch LXS from the global word line GWL.

For example, the global row switch GXS includes a fourth transistor T4.

In an embodiment, the fourth transistor T4 has a control terminal (e.g., a gate) to which the global row address signal GX_a is input, and a first terminal (e.g., a drain) and a second terminal (e.g., a source) to which the local row switch LXS and the global word line GWL are connected, respectively. For example, the fourth transistor T4 is an N-type transistor. As the voltage level of the global row address signal GX_a increases, the turn-on degree of the fourth transistor T4 increases. In addition, as the turn-on degree increases, the fourth transistor T4 allows a large amount of current to pass therethrough. On the other hand, as the voltage level of the global row address signal GX_a decreases, the turn-on degree of the fourth transistor T4 decreases.

In addition, as the turn-on degree decreases, the fourth transistor T4 allows a small amount of current to pass therethrough. Although the semiconductor device 100 in accordance with an embodiment of the present disclosure has been described using FIG. 1 as an example on the assumption that the first and second transistors T1 and T2 are P type transistors and the third and fourth transistors T3 and T4 are N type transistors, embodiments of the present disclosure are not limited thereto. In some embodiments, the first and second transistors T1 and T2 may be N-type transistors and the third and fourth transistors T3 and T4 may be P-type transistors. In some embodiments, the first to fourth transistors T1, T2, T3, and T4 may all be P-type transistors or N-type transistors.

In an embodiment, during a write operation, the first write voltage generation circuit 10 and the second write voltage generation circuit 20 provide write voltages with different levels to the global bit line GBL and the global word line GWL, respectively. For example, the first write voltage generation circuit 10 generates a write voltage at a higher voltage level compared to the second write voltage generation circuit 20. The first write voltage generation circuit 10 also generates a write voltage at a lower voltage level compared to the second write voltage generation circuit 20. As an example, when the first write voltage generation circuit 10 generates a positive voltage and provides the positive voltage to the global bit line GBL as a write voltage during a write operation, the second write voltage generation circuit 20 generates a negative voltage and provides the negative voltage to the global word line GWL as a write voltage. In addition, when the first write voltage generation circuit 10 generates a negative voltage and provides the negative voltage to the global bit line GBL during a write operation, the second write voltage generation circuit 20 generates a positive voltage and provides the positive voltage to the global word line GWL.

In an embodiment, the sensing circuit 30 is configured to sense the memory cell MC during a read operation. For example, the sensing circuit 30 senses the amount of current flowing through the memory cell MC during a read operation and outputs data stored in the memory cell MC. As an example, the sensing circuit 30 is connected to the global word line GWL, and is configured to sense the amount of current flowing from the bit line BL to the global word line GWL through the memory cell MC during a read operation. In such a case, the sensing circuit 30 is configured to generate a voltage corresponding to the amount of current flowing through the memory cell MC, to compare the level of the generated voltage with the level of a reference voltage, and to determine data stored in the memory cell MC.

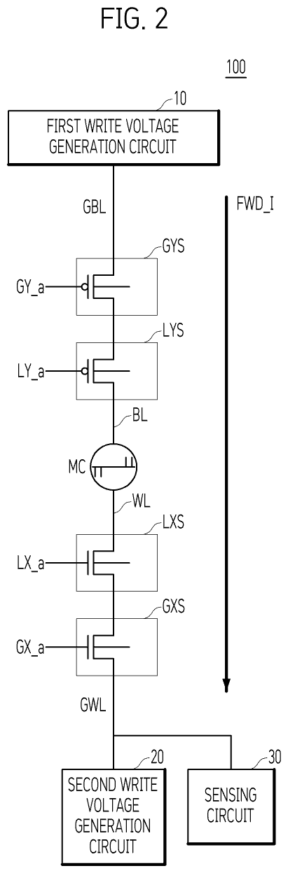

FIG. 2 is a diagram for explaining a first write operation of the semiconductor device in accordance with an embodiment of the present disclosure. FIG. 2 illustrates a memory cell MC selected by an address signal when the semiconductor device includes a plurality of memory cells. The address signal includes a column address signal and a row address signal. The column address signal includes a first column address signal (e.g., the global column address signal GY_a) and a second column address signal (e.g., the local column address signal LY_a), and the row address signal includes a first row address signal (e.g., the global row address signal GX_a) and a second row address signal (e.g., the local row address signal) LX_a.

Referring to FIG. 2, the first write operation is an operation of writing the memory cell MC by providing a first direction current FWD_I to the memory cell MC selected by the address signal.

For example, the selected memory cell MC is a memory cell MC electrically connected to the global bit line GBL through the bit line BL via the global column switch GYS and the local column switch LYS that are turned on according to the global column address signal GY_a and the local column address signal LY_a. In addition, the selected memory cell MC is a memory cell MC electrically connected to the global word line GWL through the word line WL via the global row switch GXS and the local row switch LXS that are turned on according to the global row address signal GX_a and the local row address signal LX_a. Hereinafter, for convenience of description, the selected memory cell MC is referred to as a memory cell MC.

In an embodiment, during the first write operation, the global bit line GBL receives a voltage having a higher level compared to the global word line GWL.

Accordingly, during the first write operation, the first direction current FWD_I flowing to the word line WL, the local row switch LXS, the global row switch GXS, and the global word line GWL via the global bit line GBL, the global column switch GYS, the local column switch LYS, and the bit line BL flows through the memory cell MC. In other words, during the first write operation, the first direction current FWD_I flows sequentially through the global bit line GBL, the global column switch GYS, the local column switch LYS, the bit line BL, the memory cell MC, the word line WL, the local row switch LXS, the global row switch GXS, and the global word line GWL. That is, during the first write operation, the first direction current FWD_I flows from the bit line BL to the word line WL via the memory cell MC.

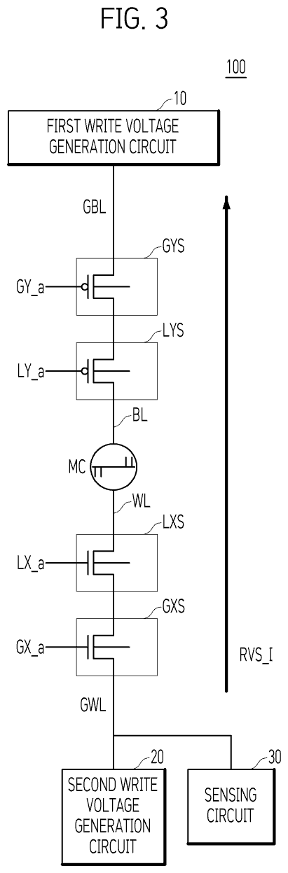

FIG. 3 is a diagram for explaining a second write operation of the semiconductor device in accordance with an embodiment of the present disclosure. Similarly to FIG. 2, FIG. 3 illustrates a memory cell MC selected by an address signal when the semiconductor device includes a plurality of memory cells. The address signal includes a column address signal and a row address signal. In addition, the column address signal includes the global column address signal GY_a and the local column address signal LY_a, and the row address signal includes the global row address signal GX_a and the local row address signal LX_a.

Referring to FIG. 3, the second write operation is an operation of writing the memory cell MC by providing a second direction current RVS_I to the memory cell MC selected by the address signal.

For example, the selected memory cell MC is a memory cell MC electrically connected to the global bit line GBL through the bit line BL via the global column switch GYS and the local column switch LYS that are turned on according to the global column address signal GY_a and the local column address signal LY_a. In addition, the selected memory cell MC is a memory cell MC electrically connected to the global word line GWL through the word line WL via the global row switch GXS and the local row switch LXS that are turned on according to the global row address signal GX_a and the local row address signal LX_a. Hereinafter, for convenience of description, the selected memory cell MC is referred to as a memory cell MC.

In an embodiment, during the second write operation, the global bit line GBL receives a voltage having a lower level compared to the global word line GWL.

Accordingly, during the second write operation, the second direction current RVS_I flowing to the bit line BL, the local column switch LYS, the global column switch GYS, and the global bit line GBL via the global word line GWL, the global row switch GXS, the local row switch LXS, and the word line WL flows through the memory cell MC. In other words, during the second write operation, the second direction current RVS_I flows sequentially through the global word line GWL, the global row switch GXS, the local row switch LXS, the word line WL, the memory cell MC, the bit line BL, the local column switch LYS, the global column switch GYS, and the global bit line GBL. That is, during the second write operation, the second direction current RVS_I flows from the word line WL to the bit line BL via the memory cell MC.

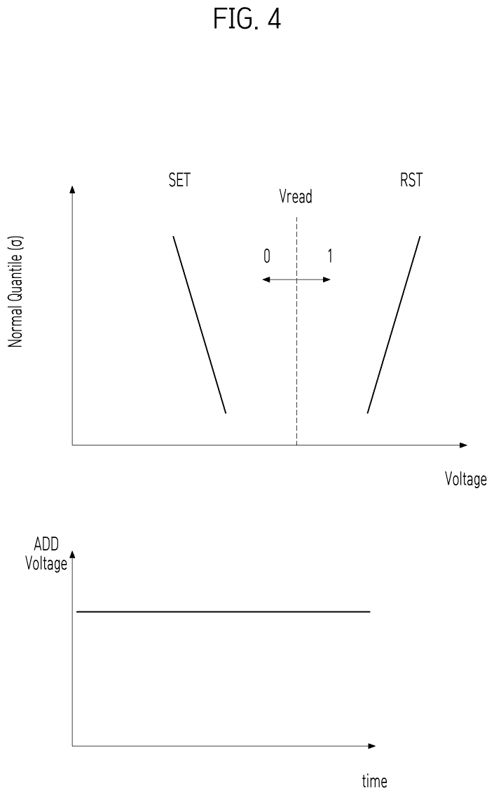

FIGS. 4, 5, and 6 are diagrams for explaining a data storage operation of a memory cell for a write operation of the semiconductor device in accordance with an embodiment of the present disclosure.

FIG. 4 is for explaining the state of the memory cell MC and the voltage levels of the address signals according to the first write operation and the second write operation illustrated in FIGS. 2 and 3.

In an embodiment, when the first direction current FWD_I flows through the memory cell MC during the first write operation, the memory cell MC is in a first state (e.g., enters a first state). In addition, when the second direction current RVS_I flows through the memory cell MC during the second write operation, the memory cell MC is in a second state (e.g., enters a second state). The first state and the second state are states different from each other.

For example, referring to FIG. 4, when the first direction current FWD_I flows through the memory cell MC, the memory cell MC enters a set state SET. On the other hand, when the second direction current RVS_I flows through the memory cell MC, the memory cell MC enters a reset state RST. The set state SET is a state in which the threshold voltage level of the memory cell MC is lower than in the reset state RST. Accordingly, when different levels of voltage are provided to the bit line BL and the word line WL during a read operation and the voltage difference between both ends of the memory cell MC is the level of a read voltage Vread, the memory cell MC in the set state SET is turned on so that current flows, and the memory cell MC in the reset state RST is turned off so that substantially no current flows.

As an example, during a read operation, a voltage having a higher level is applied to the bit line BL compared to the word line WL, and current flows to the global word line GWL via the bit line BL, the memory cell MC, and the word line WL. In other words, during a read operation, a current flows sequentially through the bit line BL, the memory cell MC, the word line WL, and the global word line GWL. In such a case, the sensing circuit 30 connected to the global word line GWL senses the amount of current that varies depending on whether the memory cell MC is turned on, and determines data stored in the memory cell MC. In the embodiment of FIG. 4, it is determined that the memory cell MC in the set state SET stores data having a first value (e.g., 0) and the memory cell MC in the reset state RST stores data having a second value (e.g., 1).

In this way, in the first and second write operations, the voltage levels ADD Voltage of address signals that turn on the global column switch GYS, the local column switch LYS, the global row switch GXS, and the local row switch LXS do not change. That is, in the first and second write operations, the voltage levels ADD Voltage of the address signals that turn on the global column switch GYS, the local column switch LYS, the global row switch GXS, and the local row switch LXS are maintained at a constant level. For example, the global column switch GYS and the local column switch LYS composed of P-type transistors are turned on by the global column address signal GY_a and the local column address signal LY_a having a first voltage level. In addition, the global row switch GXS and the local row switch LXS composed of N-type transistors are turned on by the global row address signal GX_a and the local row address signal LX_a having a second voltage level. In addition, because the first voltage level and the second voltage level that turn on different types of switches are maintained substantially constant, the turn-on degree of each switch is also maintained substantially constant.

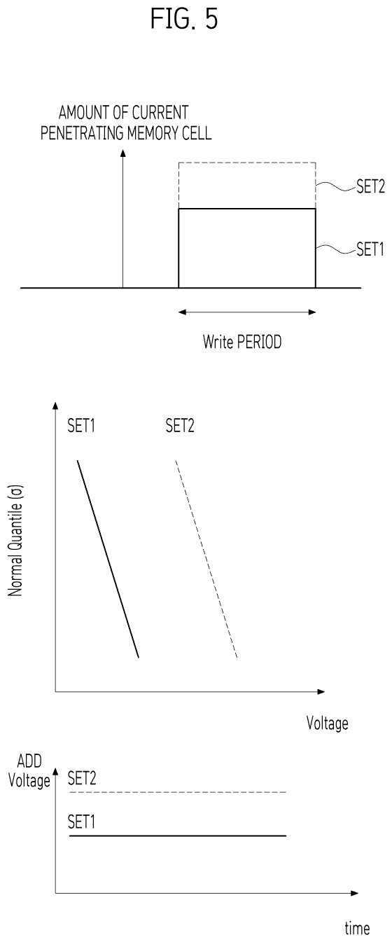

FIG. 5 is a diagram for explaining a write operation of making the memory cell MC have a first set state SET1 or a second set state SET2 (e.g., changing the memory cell MC into a first set state SET1 or a second set state SET2) by using the first write operation. In such a case, the state of the memory cell MC is in the set state SET (e.g., changes to the set state SET) when the first direction current FWD_I flows as illustrated in FIG. 2, but the set state SET varies depending on the amount of the first direction current FWD_I.

Referring to FIG. 5, the state of the memory cell MC is changed to the first set state SET1 or the second set state SET2 according to the amount of the first direction current FWD_I. For example, the threshold voltage level of the memory cell MC in the first set state SET1 is different from the threshold voltage level of the memory cell MC in the second set state SET2. More specifically, for example, the threshold voltage level of the memory cell MC in the first set state SET1 is lower than the threshold voltage level of the memory cell MC in the second set state SET2. In such a case, the amount of the first direction current FWD_I for changing the memory cell MC into the first set state SET1 is smaller than the amount of the first direction current FWD_I for changing the memory cell MC into the second set state SET2. That is, during the first write operation, the amount of the first direction current FWD_I passing through the memory cell MC in the first set state SET1 is smaller than the amount of the first direction current FWD_I passing through the memory cell MC in the second set state SET2.

Accordingly, the semiconductor device in accordance with an embodiment of the present disclosure can change the amount of the first direction current FWD_I by changing the voltage level ADD Voltage of an address signal provided to at least one of the global column switch GYS, the local column switch LYS, the global row switch GXS, and the local row switch LXS during the first write operation in order to change the state of the memory cell MC to the first set state SET1 or the second set state SET2.

For example, in order to change the state of the memory cell MC to the first set state SET1 or the second set state SET2, the voltage level ADD Voltage of the address signal provided to one or both of the global row switch GXS and the local row switch LXS composed of N-type transistors is changed.

In an embodiment, the N-type transistor allows a larger amount of current to flow as the voltage level of a signal provided to the gate thereof increases. On the other hand, the N-type transistor allows a smaller amount of current to flow as the voltage level of a signal provided to the gate thereof decreases.

Accordingly, during the first write operation, the amount of the first direction current FWD_I passing through the memory cell MC is changed according to the voltage level of the address signal provided to one or both of the global row switch GXS and the local row switch LXS.

For example, the following describes an operation of controlling the voltage level of the local row address signal LX_a provided to the local row switch LXS, in order to change the state of the memory cell MC to the first set state SET1 or the second set state SET2 during the first write operation. When the state of the memory cell MC is changed to the first set state SET1, a local row address signal LX_a having a lower voltage level is provided to the local row switch LXS compared to when the state of the memory cell MC is changed to the second set state SET2. On the other hand, when the state of the memory cell MC is changed to the second set state SET2, a local row address signal LX_a having a higher voltage level is provided to the local row switch LXS compared to when the state of the memory cell MC is changed to the first set state SET1.

Although not illustrated in FIG. 5, in order to change the state of the memory cell MC to the first set state SET1 or the second set state SET2, the voltage level ADD Voltage of the address signal provided to one or both of the global column switch GYS and the local column switch LYS composed of P-type transistors is changed.

The P-type transistor allows a larger amount of current to flow as the voltage level of a signal provided to the gate thereof decreases. On the other hand, the P-type transistor allows a smaller amount of current to flow as the voltage level of the signal provided to the gate thereof increases.

Accordingly, during the first write operation, the amount of the first direction current FWD_I passing through the memory cell MC is changed according to the voltage level of the address signal provided to one or both of the global column switch GYS and the local column switch LYS.

For example, the following describes an operation of controlling the voltage level of the local column address signal LY_a provided to the local column switch LYS, in order to change the state of the memory cell MC to the first set state SET1 or the second set state SET2 during the first write operation. When the state of the memory cell MC is changed to the first set state SET1, a local column address signal LY_a having a higher voltage level is provided to the local column switch LYS compared to when the state of the memory cell MC is changed to the second set state SET2. On the other hand, when the state of the memory cell MC is changed to the second set state SET2, a local column address signal LY_a having a lower voltage level is provided to the local column switch LYS compared to when the state of the memory cell MC is changed to the first set state SET1.

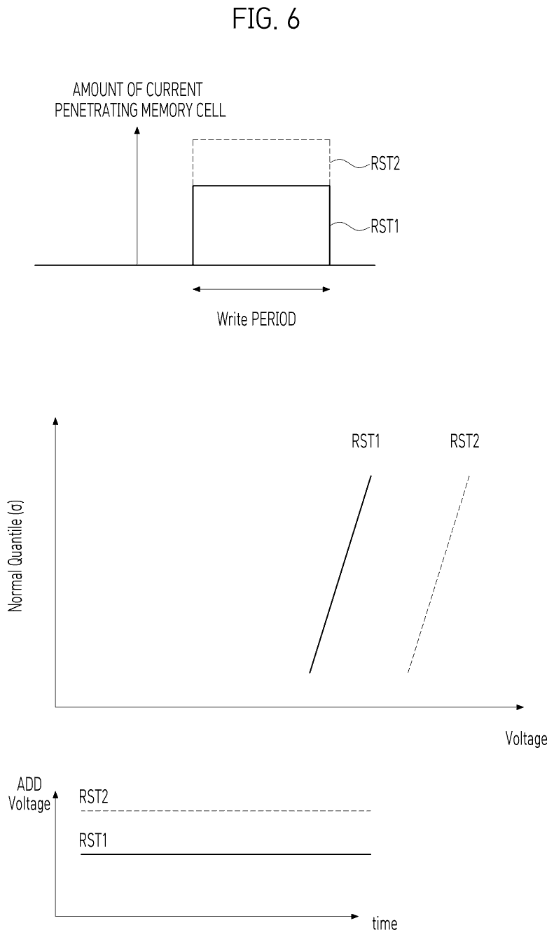

FIG. 6 is a diagram for explaining a write operation of making the memory cell MC have a first reset state RST1 or a second reset state RST2 (e.g., changing the memory cell MC into a first reset state RST1 or a second reset state RST2) by using the second write operation. In such a case, the state of the memory cell MC is in the reset state RST (e.g., is changed to the reset state RST) when the second direction current RVS_I flows as illustrated in FIG. 3, but the reset state RST varies depending on the amount of the second direction current RVS_I.

Referring to FIG. 6, the state of the memory cell MC is changed to the first reset state RST1 or the second reset state RST2 according to the amount of the second direction current RSV_I. For example, the threshold voltage level of the memory cell MC in the first reset state RST1 is different from the threshold voltage level of the memory cell MC in the second reset state RST2. More specifically, for example, the threshold voltage level of the memory cell in the first reset state RST1 is lower than the threshold voltage level of the memory cell MC in the second reset state RST2. In such a case, the amount of the second direction current RVS_I for changing the memory cell MC to the first reset state RST1 is smaller than the amount of the second direction current RVS_I for changing the memory cell MC to the second reset state RST2. That is, during the second write operation, the amount of the second direction current RVS_I passing through the memory cell MC in the first reset state RST1 is smaller than the amount of the second direction current RVS_I passing through the memory cell MC in the second reset state RST2.

Accordingly, the semiconductor device in accordance with an embodiment of the present disclosure can change the amount of the second direction current RVS_I by changing the voltage level ADD Voltage of an address signal provided to at least one of the global column switch GYS, the local column switch LYS, the global row switch GXS, and the local row switch LXS during the second write operation in order to change the state of the memory cell MC to the first reset state RST1 or the second reset state RST2.

For example, in order to change the state of the memory cell MC to the first reset state RST1 or the second reset state RST2, the voltage level ADD Voltage of the address signal provided to one or both of the global row switch GXS and the local row switch LXS composed of N-type transistors is changed.

In an embodiment, the N-type transistor allows a larger amount of current to flow as the voltage level of a signal provided to the gate thereof is higher. On the other hand, the N-type transistor allows a smaller amount of current to flow as the voltage level of a signal provided to the gate thereof is lower.

Accordingly, during the second write operation, the amount of the second direction current RVS_I passing through the memory cell MC is changed according to the voltage level of the address signal provided to one or both of the global row switch GXS and the local row switch LXS.

For example, the following describes an operation of controlling the voltage level of the local row address signal LX_a provided to the local row switch LXS, in order to change the state of the memory cell MC to the first reset state RST1 or the second reset state RST2 during the second write operation. When the state of the memory cell MC is changed to the first reset state RST1, a local row address signal LX_a having a lower voltage level is provided to the local row switch LXS compared to when the state of the memory cell MC is changed to the second reset state RST2. On the other hand, when the state of the memory cell MC is changed to the second reset state RST2, a local row address signal LX_a having a higher voltage level is provided to the local row switch LXS compared to when the state of the memory cell MC is changed to the first reset state RST1.

Although not illustrated in FIG. 6, in order to change the state of the memory cell MC to the first reset state RST1 or the second reset state RST2, the voltage level ADD Voltage of the address signal provided to one or both of the global column switch GYS and the local column switch LYS composed of P-type transistors is changed.

The P-type transistor allows a larger amount of current to flow as the voltage level of a signal provided to the gate thereof decreases. On the other hand, the P-type transistor allows a smaller amount of current to flow as the voltage level of the signal provided to the gate thereof increases.

Accordingly, during the second write operation, the amount of the second direction current RVS_I passing through the memory cell MC is changed according to the voltage level of the address signal provided to one or both of the global column switch GYS and the local column switch LYS.

For example, the following describes an operation for controlling the voltage level of the local column address signal LY_a provided to the local column switch LYS, in order to change the state of the memory cell MC to the first reset state RST1 or the second reset state RST2 during the second write operation. When the state of the memory cell MC is changed to the first reset state RST1, a local column address signal LY_a having a higher voltage level is provided to the local column switch LYS compared to when the state of the memory cell MC is changed to the second reset state RST2. On the other hand, when the state of the memory cell MC is changed to the second reset state RST2, a local column address signal LY_a having a lower voltage level is provided to the local column switch LYS compared to when the state of the memory cell MC is changed to the first reset state RST1.

As described above, the semiconductor device in accordance with an embodiment of the present disclosure can control the amount of current flowing through the memory cell MC during a write operation in order to change the state of the memory cell MC to a corresponding one of a plurality of set states or a corresponding one of a plurality of reset states. In an embodiment, the memory cell MC is in a corresponding one of a plurality of set states (e.g., the first and second set states SET1 and SET2 in FIG. 5) having different threshold voltage levels according to an amount of a first direction current (e.g., the first direction current FWD_I in FIG. 2). The amount of the first direction current is changed by controlling a turn-on degree of the column switch (e.g., the global column switch GYS, or the local column switch LYS, or both in FIG. 1), or the turn-on degree of the row switch (e.g., the global row switch GXS, or the local row switch LXS, or both in FIG. 1), or both. In an embodiment, the memory cell MC is in a corresponding one of a plurality of reset states (e.g., the first and second reset states RST1 and RST2 in FIG. 6) having different threshold voltage levels according to an amount of a second direction current (e.g., the second direction current RVS_I in FIG. 3). The amount of the second direction current is changed by controlling a turn-on degree of the column switch (e.g., the global column switch GYS, or the local column switch LYS, or both in FIG. 1), or the turn-on degree of the row switch (e.g., the global row switch GXS, or the local row switch LXS, or both in FIG. 1), or both. In such a case, the semiconductor device in accordance with an embodiment of the present disclosure can change the voltage level of an address signal for selecting the memory cell MC, in order to control the amount of current flowing through the memory cell MC during the write operation.

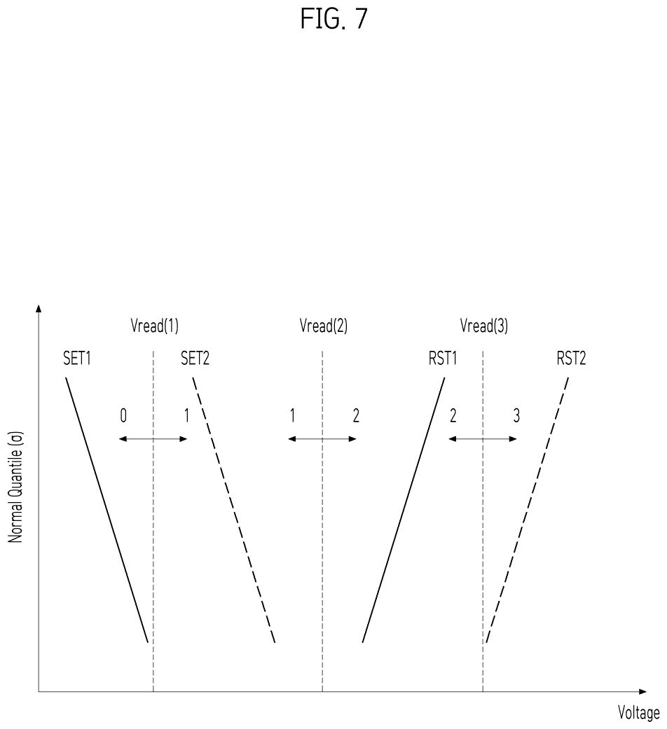

FIG. 7 is a diagram for explaining a read operation of the semiconductor device in accordance with an embodiment of the present disclosure. FIG. 7 is a diagram for explaining an operation of reading a memory cell that is in a corresponding one of a plurality of set states or a corresponding one of a plurality of reset states. In such a case, the plurality of set states include the first set state SET1 and the second set state SET2, and the plurality of reset states include the first reset state RST1 and the second reset state RST2.

Referring to FIG. 7, the threshold voltage level of the memory cell MC in the first set state SET1 is lower than the threshold voltage level of the memory cell MC in the second set state SET2. The threshold voltage level of the memory cell MC in the second set state SET2 is lower than the threshold voltage level of the memory cell MC in the first reset state RST1. The threshold voltage level of the memory cell MC in the first reset state RST1 is lower than the threshold voltage level of the memory cell MC in the second reset state RST2.

In an embodiment, the level of a first read voltage Vread(1) is lower than the level of a second read voltage Vread(2). The level of the second read voltage Vread(2) is lower than the level of a third read voltage Vread(3). In addition, the level of the first read voltage Vread(1) is a voltage level corresponding to the threshold voltage level of the memory cell MC between the first set state SET1 and the second set state SET2. The level of the second read voltage Vread(2) is a voltage level corresponding to the threshold voltage level of the memory cell MC between the second set state SET2 and the first reset state RST1. The level of the third read voltage Vread(3) is a voltage level corresponding to the threshold voltage level of the memory cell MC between the first reset state RST1 and the second reset state RST2.

In an embodiment, the first, second, and third read voltages Vread(1), Vread(2), and Vread(3) each are a difference in levels of voltages applied to both ends of the memory cell MC during the read operation. That is, the read operation is an operation of sensing a current change according to the turn-on or turn-off of the memory cell MC by providing voltages with different levels to the bit line BL and the word line WL so that the voltage level difference between both ends of the memory cell MC is one of the first to third read voltages Vread(1), Vread(2), and Vread(3). For example, the level of a voltage applied to the bit line BL during the read operation is higher than the level of a voltage applied to the word line WL. When voltages corresponding to the first to third read voltages Vread(1), Vread(2), and Vread(3) are respectively provided to both ends of the memory cell MC during the read operation, the amount of current flowing from the bit line BL to the word line WL through the memory cell MC is changed depending on the turn-on or turn-off of the memory cell MC. In such a case, the word line WL is connected to the global word line GWL through the local row switch LXS and the global row switch GXS, so that the word line WL is electrically connected to the sensing circuit 30 connected to the global word line GWL. The sensing circuit 30 senses the amount of current provided through the word line WL and the global word line GWL during the read operation to determine the state of the memory cell MC.

More specifically, the read operation of the semiconductor device in accordance with an embodiment of the present disclosure is described as follows.

The read operation of the semiconductor device in accordance with an embodiment of the present disclosure provides voltages with different levels to both ends of the memory cell MC so that the voltage level difference between both ends of the memory cell MC sequentially corresponds to the first read voltage Vread(1), the second read voltage Vread(2), and the third read voltage Vread(3). In an embodiment, a semiconductor device in accordance with an embodiment of the present disclosure sequentially provides a plurality of read voltages (e.g., the first, second, and third read voltages Vread(1), Vread(2), and Vread(3) in FIG. 7) to the memory cell MC during a read operation to determine the state of the memory cell MC. Such a semiconductor device may stop sequentially providing the read voltages when the state of the memory cell MC is determined. For example, a memory controller of the semiconductor device may sequentially provide a plurality of read voltages to the memory cell MC or stop providing the plurality of read voltages to the memory cell.

First, voltages with different levels are provided to both ends of the memory cell MC so that the voltage level difference between both ends of the memory cell MC corresponds to the first read voltage Vread(1) level. In such a case, when the memory cell MC is in the first set state SET1, the memory cell MC is turned on, and a larger amount of current is provided to the global word line GWL through the memory cell MC via the word line WL compared to when the memory cell MC is turned off. The sensing circuit 30 connected to the global word line GWL compares the level of a voltage corresponding to the amount of current passing through the memory cell MC with the level of a reference voltage. When the voltage level corresponding to the current passing through the memory cell MC is higher than the level of the reference voltage, the sensing circuit 30 determines that the memory cell MC is in the first set state SET1. When the memory cell MC is determined to be in the first set state SET1, the providing of the second and third read voltages Vread(2) and Vread(3) to the memory cell MC is stopped.

On the other hand, when the voltage level corresponding to the current passing through the memory cell MC is lower than the level of the reference voltage, the sensing circuit 30 determines that the memory cell MC is not in the first set state SET1. Subsequently, voltages with different levels are provided to both ends of the memory cell MC so that the voltage level difference between both ends of the memory cell MC corresponds to the second read voltage Vread(2) level. In such a case, when the memory cell MC is in the second set state SET2, the memory cell MC is turned on, and a larger amount of current is provided to the global word line GWL through the memory cell MC via the word line WL compared to when the memory cell MC is turned off. The sensing circuit 30 connected to the global word line GWL compares the level of a voltage corresponding to the amount of current passing through the memory cell MC with the level of a reference voltage. When the voltage level corresponding to the current passing through the memory cell MC is higher than the level of the reference voltage, the sensing circuit 30 determines that the memory cell MC is in the second set state SET2. When the memory cell MC is determined to be in the second set state SET2, the providing of the third read voltage Vread(3) to the memory cell MC is stopped.

In addition, when the voltage level corresponding to the current passing through the memory cell MC is lower than the level of the reference voltage, the sensing circuit 30 determines that the memory cell MC is not in the second set state SET2. Subsequently, voltages with different levels are provided to both ends of the memory cell MC so that the voltage level difference between both ends of the memory cell MC corresponds to the third read voltage Vread(3) level. In such a case, when the memory cell MC is in the first reset state RST1, the memory cell MC is turned on, and a larger amount of current is provided to the global word line GWL through the memory cell MC via the word line WL compared to when the memory cell MC is turned off. The sensing circuit 30 connected to the global word line GWL compares the level of a voltage corresponding to the amount of current passing through the memory cell MC with the level of the reference voltage. When the voltage level corresponding to the current passing through the memory cell MC is higher than the level of the reference voltage, the sensing circuit 30 determines that the memory cell MC is in the first reset state RST1. In a state in which the third read voltage Vread(3) has been provided, when the voltage level corresponding to the current passing through the memory cell MC is lower than the level of the reference voltage, the sensing circuit 30 determines that the memory cell MC is in the second reset state RST2. The first set state SET1 indicates a state in which a decimal number 0 is stored in the memory cell MC. The second set state SET2 means a state in which a decimal number 1 is stored in the memory cell MC. The first reset state RST1 means a state in which a decimal number 2 is stored in the memory cell MC. The second reset state RST2 means a state in which a decimal number 3 is stored in the memory cell MC. In such a case, the decimal number 0 corresponds to a combination of binary numbers 00, the decimal number 1 corresponds to a combination of binary numbers 01, the decimal number 2 corresponds to a combination of binary numbers 10, and the decimal number 3 corresponds to a combination of binary numbers 11. Accordingly, the first set state SET1 indicates a state in which a combination of binary numbers 00 is stored in the memory cell MC. The second set state SET2 indicates a state in which a combination of binary numbers 01 is stored in the memory cell MC. The first reset state RST1 indicates a state in which a combination of binary numbers 10 is stored in the memory cell MC. The second reset state RST2 indicates a state in which a combination of binary numbers 11 is stored in the memory cell MC.

As described above, the read operation of the semiconductor device in accordance with an embodiment of the present disclosure can sequentially provide a plurality of read voltages in an order increasing from a read voltage having a lowest voltage level to a read voltage having a highest voltage level to both ends of the memory cell MC in order to determine the state of the memory cell in a specific one of a plurality of set states and a plurality of reset states.

Although some embodiments of the present disclosure have been described above with reference to the accompanying drawings, embodiments of the present disclosure are not limited to the above embodiments. Various types of substitutions, modifications, and changes for the embodiments may be made by those skilled in the art, to which the present disclosure pertains, without departing from the technical idea of the present disclosure defined in the following claims.

What is claimed is:

1. A semiconductor device comprising:
a column switch that electrically connects a global bit line to a bit line or disconnects the global bit line from the bit line;
a row switch that electrically connects a global word line to a word line or disconnects the global word line from the word line; and
a memory cell electrically connected between the bit line and the word line,
wherein, during a write operation, one or both of a turn-on degree of the column switch and a turn-on degree of the row switch are changed.

2. The semiconductor device of claim 1, wherein the column switch is turned on or off on the basis of a column address signal, and
wherein the turn-on degree of the column switch is changed according to a voltage level of the column address signal.

3. The semiconductor device of claim 1, wherein the column switch is a first column switch, the device further comprising a second column switch that electrically connects the global bit line to the bit line or disconnects the global bit line from the bit line,
wherein the first and second column switches are turned on or off on the basis of first and second column address signals, and
wherein the turn-on degree of the first column switch is changed according to a voltage level of the first column address signal, or a turn-on degree of the second column switch is changed according to a voltage level of the second column address signal, or both.

4. The semiconductor device of claim 1, wherein the row switch is turned on or off on the basis of a row address signal, and
wherein the turn-on degree of the row switch is changed according to a voltage level of the row address signal.

5. The semiconductor device of claim 1, wherein the row switch is a first row switch, the device further comprising a second row switch that electrically connects the global word line to the word line or disconnects the global word line from the word line,
wherein the first and second row switches are turned on or off on the basis of first and second row address signal, and
wherein the turn-on degree of the first row switch is changed according to a voltage level of the first row address signal, or a turn-on degree of the second row switch is changed according to a voltage level of the second row address signal, or both.

6. The semiconductor device of claim 1, wherein, during the write operation, when a voltage having a higher level is provided to the bit line compared to the word line and a first direction current flows, the memory cell is in a set state, and
wherein, during the write operation, when a voltage having a lower level is provided to the bit line compared to the word line and a second direction current flows, the memory cell is in a reset state.

7. The semiconductor device of claim 6, wherein the memory cell is in a corresponding one of a plurality of set states having different threshold voltage levels according to an amount of the first direction current, the amount of the first direction current being changed by controlling the turn-on degree of the column switch, or the turn-on degree of the row switch, or both.

8. The semiconductor device of claim 6, wherein the memory cell is in a corresponding one of a plurality of reset states having different threshold voltage levels according to an amount of the second direction current, the amount of the second direction current being changed by controlling the turn-on degree of the column switch, or the turn-on degree of the row switch, or both.

9. The semiconductor device of claim 6, wherein the device sequentially provides a plurality of read voltages having different voltage levels to the memory cell to determine a state of the memory cell during a read operation.

10. The semiconductor device of claim 9, wherein the device sequentially provides the plurality of read voltages to the memory cell in an order increasing from a read voltage having a lowest voltage level to a read voltage having a highest voltage level.

11. The semiconductor device of claim 10, wherein the device stops sequentially providing the read voltages sequentially to the memory cell when the state of the memory cell is determined.

12. The semiconductor device of claim 9, wherein each of the read voltages corresponds to a voltage level difference between the bit line and the word line.

13. The semiconductor device of claim 9, further comprising:
a sensing circuit connected to the global word line and determining the state of the memory cell according to an amount of a current provided from the global word line during the read operation.

14. An operating method of a semiconductor device, comprising:
electrically connecting a global bit line to a bit line during a write operation;
electrically connecting a global word line to a word line during the write operation;
determining a direction of a current to flow through a memory cell, the memory cell being connected between the bit line and the word line; and
adjusting an amount of the current flowing in a specific direction.

15. The operating method of claim 14, wherein electrically connecting the global bit line to the bit line comprises:
turning on one or both of a first column switch and a second column switch that are connected between the global bit line and the bit line on the basis of a column address signal.

16. The operating method of claim 15, wherein adjusting the amount of the current comprises:
adjusting a turn-on degree of the first column switch, or a turn-on degree of the second column switch, or both, by adjusting a voltage level of the column address signal.

17. The operating method of claim 14, wherein electrically connecting the global word line to the word line comprises:
turning on one or both of a first row switch and a second row switch that are connected between the global word line and the word line on the basis of a row address signal.

18. The operating method of claim 17, wherein adjusting the amount of the current comprises:
adjusting a turn-on degree of the first row switch, or a turn-on degree of the second row switch, or both, by adjusting a voltage level of the row address signal.

19. The operating method of claim 14, wherein a state of the memory cell is in a set state or a reset state according to the determined direction of the current.

20. The operating method of claim 19, wherein the set state comprises a plurality of set states having different threshold voltage levels, and
wherein the state of the memory cell is in a corresponding one of the plurality of set states according to the amount of the current.

21. The operating method of claim 19, wherein the reset state comprises a plurality of reset states having different threshold voltage levels, and
wherein the state of the memory cell is in a corresponding one of the plurality of reset states according to the amount of the current.

22. The operating method of claim 14, further comprising:
sequentially providing a plurality of read voltages having different levels to the memory cell during a read operation.

23. The operating method of claim 22, wherein sequentially providing the plurality of read voltages comprises:
sequentially providing the read voltages to the memory cell in an order increasing from a read voltage having a lowest level to a read voltage having a highest level.

24. The operating method of claim 22, wherein sequentially providing the plurality of read voltages is stopped when a state of the memory cell is determined.

25. A semiconductor device comprising:
a memory cell that stores data;
a first transistor that electrically connects a global bit line to a bit line or disconnects the global bit line from the bit line; and
a second transistor that electrically connects a global word line to a word line or disconnects the global word line from the word line,
wherein the memory cell is electrically connected between the bit line and the word line, and
wherein, during a write operation, a turn-on degree of the first transistor is changed according to a level of a voltage applied to a gate of the first transistor, a turn-on degree of the second transistor is changed according to a level of a voltage applied to a gate of the second transistor, or both.

26. The semiconductor device of claim 25, wherein, during the write operation, when a voltage having a higher level is provided to the bit line compared to the word line and a first direction current flows, the memory cell is in a set state, and
wherein, during the write operation, when a voltage having a lower level is provided to the bit line compared to the word line and a second direction current flows, the memory cell is in a reset state.

27. The semiconductor device of claim 26, wherein a state of the memory cell is in a corresponding one of a plurality of set states having different threshold voltage levels on the basis of an amount of the first direction current, the amount of the first direction current being changed according to the level of the voltage applied to the gate of the first transistor, or the level of the voltage applied to the gate of the second transistor, or both.

28. The semiconductor device of claim 26, wherein a state of the memory cell is in a corresponding one of a plurality of reset states having different threshold voltage levels on the basis of an amount of the second direction current, the amount of the second direction current being changed according to the level of the voltage applied to the gate of the first transistor, or the level of the voltage applied to the gate of the second transistor, or both.

29. The semiconductor device of claim 26, wherein the device sequentially provides a plurality of read voltages having different voltage levels to the memory cell to determine a state of the memory cell during a read operation.

30. The semiconductor device of claim 29, wherein the device sequentially provides the plurality of read voltages to the memory cell in an increasing order from a read voltage having a lowest voltage level to a read voltage having a highest voltage level.

31. The semiconductor device of claim 30, wherein the device stops sequentially providing the read voltages to the memory cell when the state of the memory cell is determined.

32. The semiconductor device of claim 25, wherein the memory cell is a variable resistance memory cell.

33. The semiconductor device of claim 32, wherein the variable resistance memory cell comprises a chalcogenide material.

34. The semiconductor device of claim 32, wherein the variable resistance memory cell stores data through a phase change of the chalcogenide material.
